(19) United States
(12) Patent Application Publication
(10) Pub. No.: US 2015/0047822 A1
(43) Pub. Date: Feb. 19, 2015

(54) HEAT SINK DEVICE WITH EMI SHIELDING FUNCTION

(71) Applicant: HON HAI PRECISION INDUSTRY CO., LTD., New Taipei (TW)

(72) Inventors: CHIH-HAO LIN, New Taipei (TW); YI-HSIEN LEE, New Taipei (TW)

(21) Appl. No.: 14/461,450

(22) Filed: Aug. 18, 2014

(30) Foreign Application Priority Data
Aug. 16, 2013 (TW) 102129438

(51) Int. Cl. H05K 9/00; H05K 7/20

(52) U.S. Cl. CPC H05K 9/0081; H05K 7/2039
USPC 165/185

(57) ABSTRACT

A heat sink is configured to dissipate heat generated by an electronic component and protect the electronic component from Electromagnetic Interference (EMI). The heat sink comprises a base and a number of waveguides extending out from the base. A number of through holes is defined through the base. Each of the waveguides is a hollow but blind tube communicating with a through hole.

### FIELD

The subject matter herein generally relates to heat sinks.

### BACKGROUND

A conventional heat sink can be mounted on an electronic component for dissipating heat generated by the electronic component. However, electromagnetic interference (EMI) often occurs between neighboring electronic components due to inductive coupling, and the conventional heat sink does not shield the electronic component from external EMI.

### BRIEF DESCRIPTION OF THE DRAWINGS

Implementations of the present technology will now be described, by way of example only, with reference to the attached figures.

FIG. 1 is an isometric view of an embodiment of a heat sink.

FIG. 2 is similar to FIG. 1, but viewed from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “comprising” means “including, but not necessarily limited to”; it specifically indicates open-ended inclusion or membership in a so-described combination, group, series and the like.

The present disclosure is described in relation to a heat sink.

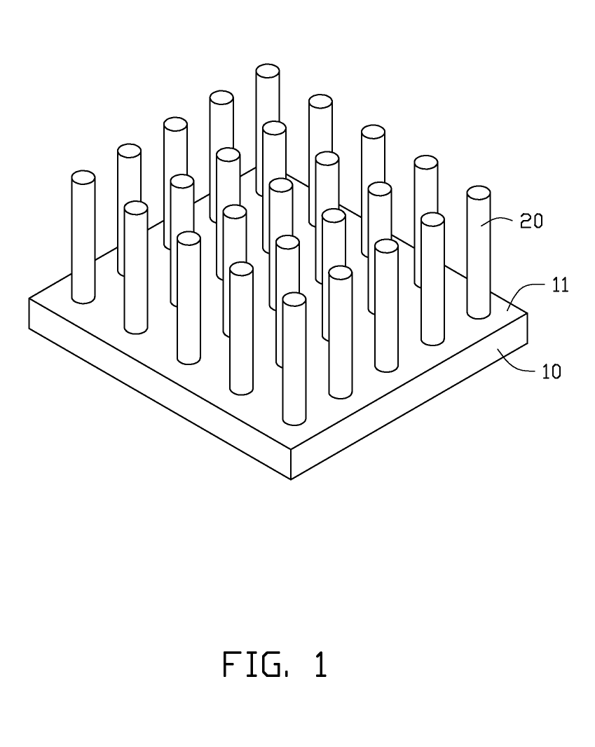

FIG. 1 illustrates a heat sink for dissipating heat generated by an electronic component and protecting the electronic component from electromagnetic interference (EMI).

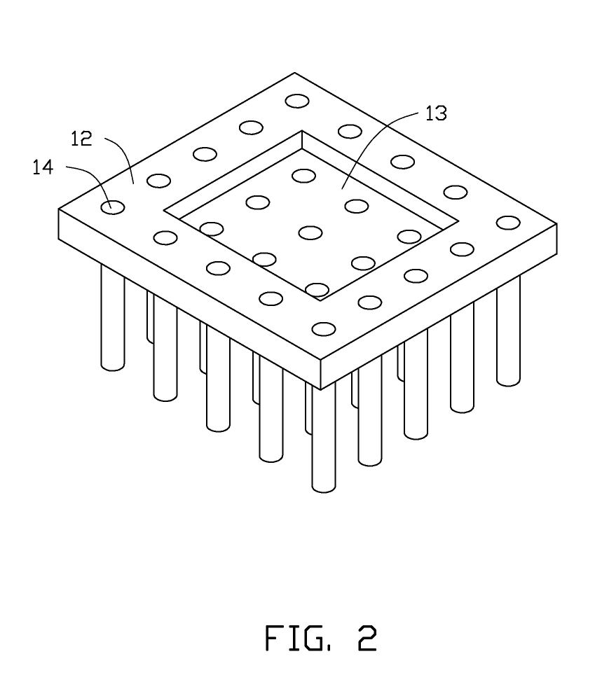

FIG. 2 illustrates the heat sink from another angle.

The heat sink can comprise a base 10 and a plurality of waveguides 20 extending out from the base 10. A receiving cutout 13 is defined in a lower surface 12 of the base 10. The electronic component is received in the receiving cutout 13. A plurality of through holes 14 is defined through the base 10.

Each waveguide 20 is a hollow tube made of metal, or other thermally conductive materials. One end of each waveguide 20 is open to communicate with a corresponding through hole 14 of the base 10. Another end of each waveguide 20 is closed. The base 10 and the waveguide 20 can be attached together or integrally formed.

During assembly, the heat sink can be mounted on the electronic component, with the electronic component received in the receiving cutout 13. Thus, the heat sink is capable of not only protecting the electronic component received in the receiving cutout 13 from electromagnetic waves generated by other electronic components, but also preventing electromagnetic waves generated by the electronic component received in the receiving cutout 13 from interfering with the other electronic components. The heat sink is also capable of effectively dissipating heat generated by the electronic component received in the receiving cutout 13.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A heat sink for dissipating heat generated by an electronic component and protecting the electronic component from Electromagnetic Interference (EMI), the heat sink comprising:
a base;
a plurality of waveguides extending from the base; and
a plurality of through holes running through the base;
wherein each one of the plurality of waveguides is a hollow tube communicating with a corresponding one of the plurality of through holes.

2. The heat sink of claim 1, wherein each waveguide is made of metal, or other thermal conductive materials.

3. The heat sink of claim 1, wherein a receiving cutout is defined in a lower surface of the base and is configured to receive the electronic component.

4. The heat sink of claim 1, wherein one end of each waveguide is open to communicate with a corresponding through hole of the base and another end of each waveguide is closed.

5. The heat sink of claim 1, wherein the base and the waveguide are integrally formed.
